(19) United States
(12) Patent Application Publication
(10) Pub. No.: US 2025/0112628 A1
(43) Pub. Date: Apr. 3, 2025

(54) DRIVER INCLUDING PARALLEL RESISTIVE PATHS

(71) Applicants: Isaac Abraham, Tacoma, WA (US); Rodolfo Kiyama Armendariz, Portland, OR (US); Michael W. Altmann, Folsom, CA (US); Jonathan Kolet Gamble, McMinnville, OR (US); Benjamin Gordon, Seattle, WA (US)

(72) Inventors: Isaac Abraham, Tacoma, WA (US); Rodolfo Kiyama Armendariz, Portland, OR (US); Michael W. Altmann, Folsom, CA (US); Jonathan Kolet Gamble, McMinnville, OR (US); Benjamin Gordon, Seattle, WA (US)

(21) Appl. No.: 18/374,825

(22) Filed: Sep. 29, 2023

(51) Int. Cl. H03K 17/06; H03K 17/687; H03K 19/0185

(52) U.S. Cl. CPC H03K 17/063; H03K 17/687; H03K 19/018507; H03K 19/018585

(57) ABSTRACT

Some embodiments include an apparatus having a conductive pad, a first supply node, a second supply node, and a driver. The driver includes first transistors coupled between the first supply node and a number of nodes, and second transistors coupled between the second node and the number of nodes. The driver also includes circuit paths coupled between the conductive pad and respective nodes of the number of nodes. At least one of the circuit paths includes parallel-connected resistors. At least two of the circuit paths include a single resistor.

### BACKGROUND

Many components in electronic items (e.g., cellular phones, computers, and internet of things [IoT]) have drivers, which include circuit elements (e.g., transistors), to transmit or receive information in the form of signals. A driver is normally designed to operate at specific parameters including driver's resistance. Resistors are normally included in the driver to provide a range of resistance. A particular resistance in the range of resistance can be selected to be a specific resistance for driver. The range of resistance is often associated with codes, which are used to select the specific resistance. Conventional drivers (e.g., wireline drivers) are normally implemented with binary weighted design to provide a range of resistance. In a binary weighted design, the resistors used to provide the range of resistance are arranged in a binary weighted pattern. In such a binary weighted design, the relationship between the range of resistance and codes often exhibits significant nonlinearity, such that some parameters (e.g., delta R) in the range of resistance are outside normal specifications. Therefore, in the binary weighted design, only a small sub-range within the range of resistance is useful for purposes of selecting the resistance for the driver. This can cause the driver using a binary weight design to have drawbacks. For example, the driver may have one or of the following drawbacks: a larger number of bits than necessary may be needed for a specific driver's resistance range, a larger physical size than necessary, a longer search time for a specific driver's resistance, and less feasible for updating of driver's resistance.

### BRIEF DESCRIPTION OF THE DRAWINGS

FIG. 1 shows an apparatus including devices, according to some embodiments described herein.

FIG. 2A shows a driver including circuit paths coupled to a conductive pad, according to some embodiments described herein.

FIG. 2B and FIG. 2C show example of circuit paths of the driver of FIG. 2A in which the circuit paths include parallel-connected resistors, according to some embodiments described herein.

FIG. 3 shows a chart illustrating an example of resistor quantity (the number of resistors) in the circuit paths of the driver of FIG. 2A for providing a resistance range, according to some embodiments described herein.

FIG. 4 shows a chart illustrating resistances (e.g., 32 selectable resistances) of the resistance range (e.g., 24 ohms to 120 ohms) of driver of FIG. 2A in which the resistances can be selected by selectively activating and deactivating the circuit paths of the driver, according to some embodiments described herein.

FIG. 5A and FIG. 5B show charts illustrating an encoding scheme that uses thermometer bits to encode the resistances of the resistance range of the driver of FIG. 2A when output data information has a value corresponding to logic one, according to some embodiments described herein.

FIG. 6A and FIG. 6B show charts illustrating an encoding scheme that uses thermometer bits to encode the resistances of the resistance range of the driver of FIG. 2A when output data information has a value corresponding to logic zero, according to some embodiments described herein.

FIG. 7 shows a chart illustrating an example of resistor quantity in selected circuit paths among the circuit paths of the driver of FIG. 2A to provide an extended resistance range for an extended termination resistance, according to some embodiments described herein.

FIG. 8 shows a chart illustrating resistances (e.g., 8 selectable resistances) of the extended resistance range (e.g., 120 ohms to 240 ohms) associated with FIG. 7 in which the resistances can be selected by selectively activating and deactivating the circuit paths of the driver of FIG. 2A, according to some embodiments described herein.

FIG. 9 is a graph showing relationship between code information and a resistance range provided by the driver of FIG. 2A, according to some embodiments described herein.

FIG. 10 shows an apparatus in the form of a system, according to some embodiments described herein.

FIG. 11 shows a method of operating an apparatus, according to some embodiments described herein.

### DETAILED DESCRIPTION

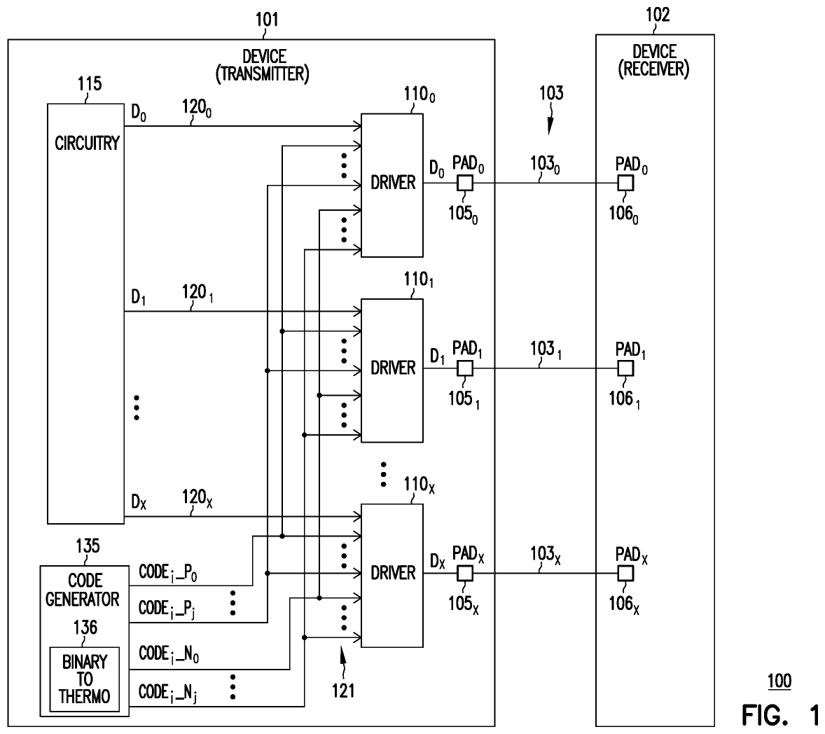

The techniques described herein involve a device that includes a driver and associated circuitry to provide a resistance range for the driver. A specific resistance can be selected from the resistance range for the driver. The selected resistance can be either an output resistance or a termination resistance. The device can operate in a transmitting mode to transmit information to another device or in a receiving mode to receive information from another device. The output resistance can be used during the transmitting mode. The termination resistance can be used during the receiving mode. The driver of the device is coupled to a conductive pad of the device. The conductive pad can be an input/output (I/O) conductive pad. The device can use the conductive pad to transmit information during a transmitting mode and to receive information during a receiving mode. The driver of the device can include circuit paths that include resistors coupled to the conductive pad. The resistors are arranged in a non-binary weighted pattern. The resistors can provide a resistance range having selectable resistances, which can be selected to provide the driver's output resistance or driver's termination resistance. The non-binary weighted pattern of the resistors allows the resistance range to have a linearity profile. This linearity of the resistance range allows an entire resistance range to be used for selecting the output resistance or the termination resistance. In comparison with some conventional drivers (e.g., drivers using resistors having binary weighted pattern) the described driver can have a smaller size for given resistance range, a larger usable resistance range for a given driver's size, a reduced search time associated with selecting the resistance for the driver, and a feasible on-the-fly updates associated with driver's resistance. These and other improvements and benefits of the described techniques are discussed in more detail below with reference to FIG. 1 through FIG. 11.

FIG. 1 shows an apparatus 100 including devices 101 and 102, according to some embodiments described herein. Apparatus 100 can include or be included in an electronic device or system, such as a computer (e.g., desktop, laptop, or notebook), a tablet, a cellular phone, a system on chip (SoC), a system in a package (SiP), or other electronic devices or systems. Each of devices 101 and 102 can include an integrated circuit (IC), such as an IC chip. Devices 101 and 102 can include a combination of a controller (e.g., processors (e.g., central processing unit [CPU]), graphics controller, input/output (I/O) controller, or memory controller), a memory device, and/or other electronic devices.

Device 101 can include conductive pads 105₀ through 105_{X}, which can include conductive I/O pads. Device 102 can include conductive pads 106₀ through 106_{X}, which can include conductive I/O pads. Conductive pads 105₀ through 105_{X} and 106₀ through 106_{X} allow respective devices 101 and 102 to communicate with each other in the form of electrical signals through a channel 103 coupled to conductive pads 105₀ through 105_{X} and 106₀ through 106_{X}. Conductive pads 105₀ through 105_{X} and 106₀ through 106_{X} can includes conductive pins, conductive bumps, conductive balls, or other types of conductive connections.

Channel 103 can include lanes 103₀ through 103_{X} to conduct signals between devices 101 and 102. Each of lanes 103₀ through 103_{X} can be a bi-directional lane to allow transmission of signals from device 101 to device 102 or from device 102 to device 101. Each of lanes 103₀ through 103_{X} can include a single conductive line (or alternatively multiple conductive lines). The conductive lines can include conductive traces on a circuit board where devices 101 and 102 are located. In an example, the conductive lines can include conductive traces (e.g., metal-based conductive traces) of a bus on a circuit board (e.g., printed circuit board of an electronic system). In an alternative arrangement, channel 103 does not have to include conductive lines on a circuit board. For example, channel 103 can include a medium (e.g., air) for wireless communication between devices 101 and 102, or other types of medium (e.g., conductive paths within an IC package).

As shown in FIG. 1, device 101 can include drivers (e.g., output drivers) 110₀ through 110_{X} having respective outputs (e.g., output nodes) coupled to respective conductive pads 105₀ through 105_{X} to provide (e.g., output) information D₀ through D_{X} to respective conductive pads 105₀ through 105_{X}. Device 101 can include circuitry 115 that can include memory circuits (e.g., to store information) and other circuits (e.g., to provide control information). Device 101 can include conductive lines 120₀ through 120_{X} coupled to respective inputs (e.g., input nodes) 121 of drivers 110₀ through 110_{X} to provide respective information D₀ through D_{X} to drivers 110₀ through 110_{X}, respectively. Information D₀ through D_{X} can be data information (e.g., output data) and other information (e.g., command, address, control, and clock).

Device 101 can include a code generator 135 to generate code information (e.g., bits) Codeᵢ_P₀ through Codeᵢ_Pⱼ and code information Codeᵢ_N₀ through Codeᵢ_Nⱼ. For simplicity, code information Codeᵢ_P₀ through Codeᵢ_Pⱼ and code information Codeᵢ_N₀ through Codeᵢ_Nⱼ are also referred to as Codeᵢ_P₀ through Codeᵢ_Pⱼ and Codeᵢ_N₀ through Codeᵢ_Nⱼ, respectively, (without the term “code information”).

Device 101 can provide Codeᵢ_P₀ through Codeᵢ_Pⱼ and Codeᵢ_N₀ through Codeᵢ_Nⱼ to inputs 121 of drivers 110₀ through 110_{X}. Based on the values of Codeᵢ_P₀ through Codeᵢ_Pⱼ and Codeᵢ_N₀ through Codeᵢ_Nⱼ, each of drivers 110₀ through 110_{X} can provide a resistance (output resistance) R_{ON} or a resistance (on-die termination resistance) R_{ODT}. The value of resistance R_{ON} or resistance R_{ODT} can be based on the value of Codeᵢ_P₀ through Codeᵢ_Pⱼ and Codeᵢ_N₀ through Codeᵢ_Nⱼ. Resistance R_{ON} and resistance R_{ODT} can have different values (in ohms units). Codeᵢ_P₀ through Codeᵢ_Pⱼ and Codeᵢ_N₀ through Codeᵢ_Nⱼ can also allow drivers 110₀ through 110_{X} to provide information D₀ through D_{X} at conductive pads 105₀ through 105_{X} with values that reflect the values of information D₀ through D_{X} from circuitry 115.

Code generator 135 can include a binary-to-thermometer converter 136 to convert the value of binary code information (e.g., binary bits) into thermometer code information (e.g., thermometer bits). Codeᵢ_P₀ through Codeᵢ_Pⱼ and Codeᵢ_N₀ through Codeᵢ_Nⱼ can be thermometer codes that include respective thermometer bits provided to inputs 121 of drivers 110₀ through 110_{X}.

Device 101 can have different modes (operating modes). For example, device 101 can have a transmitting mode and a receiving mode. In a transmitting mode, device 101 can transmit information (e.g., output data information) D₀ through D_{X} to respective conductive pad 105₀ through 105_{X}. In a receiving mode, device 101 can receive information (e.g., input data information) sent from device 102 conductive pad 105₀ through 105_{X}. Devices 101 can change (switch) between the transmitting mode and the receiving mode at different times. In a transmitting mode, device 101 can select values (e.g., bit values) for Codeᵢ_P₀ through Codeᵢ_Pⱼ and Codeᵢ_N₀ through Codeᵢ_Nⱼ, such that each of driver 110₀ through 110_{X} can have resistance R_{ON} that has a selected resistance value (e.g., predetermined resistance value based on specifications associated with device 101). In a receiving mode, device 101 can select values (e.g., bit values) for Codeᵢ_P₀ through Codeᵢ_Pⱼ and Codeᵢ_N₀ through Codeᵢ_Nⱼ, such that each of driver 110₀ through 110_{X} can have resistance R_{ODT} with a selected resistance value (e.g., predetermined resistance value based on specifications associated with device 101).

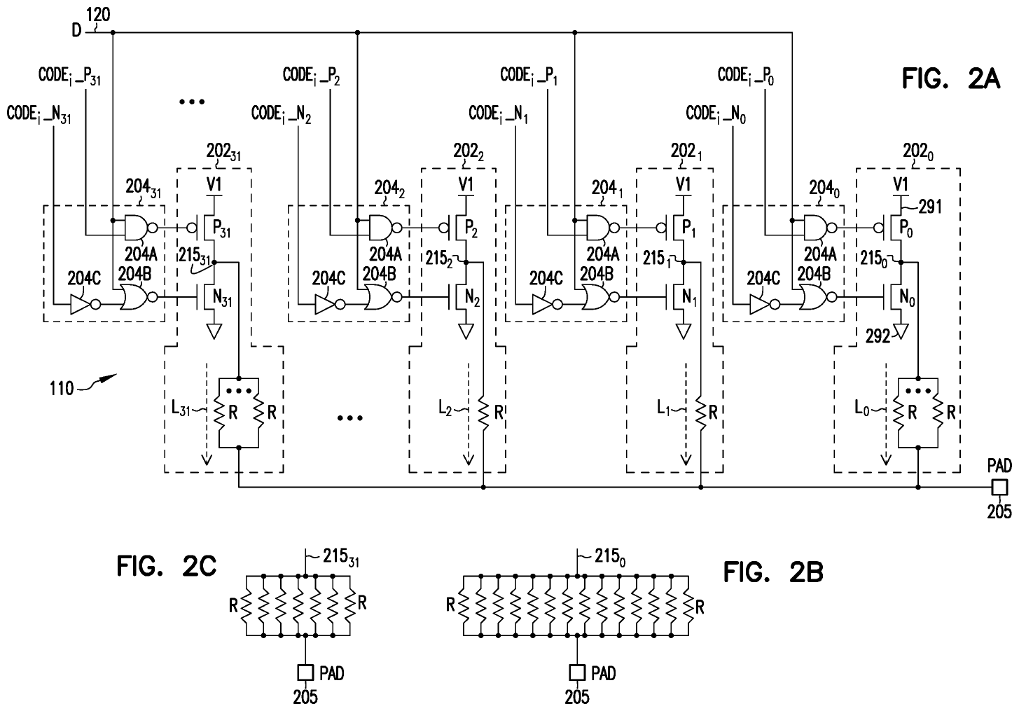

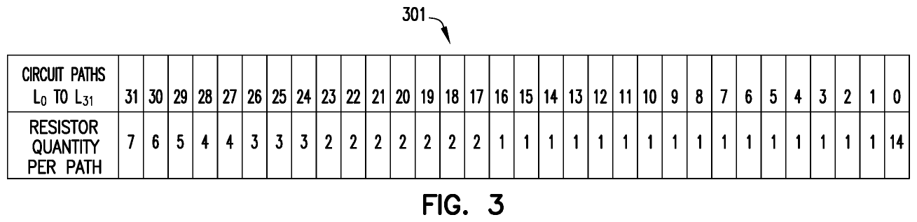

FIG. 2A shows a driver 110 including circuit paths L₀ through L₃₁ coupled to a conductive pad 205, according to some embodiments described herein. Driver 110 can represent (e.g., can be) one of drivers 110₀ through 110_{X} of FIG. 1. Conductive line 120 in FIG. 2A and associated information D can represent one of conductive lines 120₀ through 120_{X} and one of information D₀ through D_{X}, respectively, of FIG. 1. Conductive pad 205 in FIG. 2A can represent one of conductive pads 105₀ through 105_{X} of FIG. 1.

As shown in FIG. 2A, driver 110 can include transistors P₀ through P₃₁ and N₀ through N₃₁ coupled to respective circuit paths L₀ through L₃₁. Transistors P₀ through P₃₁ and N₀ through N₃₁ and circuit paths L₀ through L₃₁ can form respective circuits 202₀ through 202₃₁. Circuits 202₀ through 202₃₁ can be called legs of driver 110. Transistors P₀ through P₃₁ can include p-type transistors. Transistors N₀ through N₃₁ can include n-type transistors. An example of a p-type transistor includes a p-type field-effect transistor (FET), such as p-type metal-oxide semiconductor (PMOSFET or PMOS). Other p-type transistors can be used. An example of an n-type transistor includes n-type FET, such as n-type metal-oxide semiconductor (NMOSFET or NMOS). Other n-type transistors can be used.

Driver 110 can also include circuits (e.g., logic circuits) 204₀ through 20431 coupled to respective gates (not labeled) of transistors P₀ through P₃₁ and gates (not labeled) of transistors N₀ through N₃₁. Circuits 204₀ through 204₃₁ can also include respective nodes (e.g., input nodes) coupled to the same node 120 to receive the same information D. In this description, conductive line and conductive node (or node) are used interchangeably. For example, conductive line 120 and node 120 are used interchangeably. Node 120 can also be called data input node 120.

As shown in FIG. 2A, circuits 204₀ through 204₃₁ can also include inputs (e.g., input nodes, not labeled) to receive Codeᵢ_P₀ through Codeᵢ_P₃₁ and Codeᵢ_N₀ through Codeᵢ_N₃₁. Codeᵢ_P₀ through Codeᵢ_P₃₁ can include thermometer bits. Codeᵢ_N₀ through Codeᵢ_N₃₁ can include thermometer bits. The values of Codeᵢ P₀ through Codeᵢ_P₃₁ can be different from the values of Codeᵢ_N₀ through Codeᵢ_N₃₁. Thus, the values of thermometer bits included in Codeᵢ_P₀ through Codeᵢ_P₃₁ can be different from the values of thermometer bits included in Codeᵢ_N₀ through Codeᵢ_N₃₁.

FIG. 2A shows an example of 32 circuits 202₀ through 202₃₁, 32 transistors P₀ through P₃₁, 32 transistors N₀ through N₃₁, and 32 circuits 204₀ through 204₃₁. However, the number of circuits 202₀ through 202₃₁, transistors P₀ through P₃₁, transistors N₀ through N₃₁, and circuits 204₀ through 204₃₁ can vary. The number of circuits 202₀ through 202₃₁ can depend on the resistance range of resistance R_{ON} or resistance R_{ODT} of driver 110 and the value of a code information used for selecting resistance R_{ON} or resistance R_{ODT} from the resistance range.

As shown in FIG. 2A, driver 100 can include supply nodes 291 and 292. Supply node 291 can receive (can be coupled to) a voltage V1. For simplicity, only one supply node 291 (associated with voltage V1) is labeled in FIG. 2A. Supply node 291 can be coupled to or can be part of supply voltage (e.g., voltage V1 can be supply voltage Vcc) of device 101 (FIG. 1) where driver 110 (FIG. 2A) is located. Supply node 292 can be coupled to or can be part of supply voltage (e.g., supply voltage Vss, not labeled) of device 101 that can be part of a ground connection (e.g., ground potential). For simplicity, only one supply node 292 is labeled in FIG. 2A.

As shown in FIG. 2A, circuits 202₀ through 202₃₁ can include respective nodes (e.g., output nodes) 215₀ through 215₃₁. Nodes 215₀ through 215₃₁ can include (e.g., can be coupled) respective sources (source terminals, not labeled) of transistors P₀ through P₃₁ and respective drains (drain terminals, not labeled) of transistors N₀ through N₃₁.

As shown in FIG. 2A, transistors P₀ through P₃₁ can be coupled between supply node 291 and respective nodes 215₀ through 215₃₁. FIG. 2A shows separate supply nodes 291 associated with circuits 202₀ through 202₃₁. However, supply nodes 291 associated with circuits 202₀ through 202₃₁ can be the same node. Transistors N₀ through N₃₁ can be coupled between supply node 292 and respective nodes 215₀ through 215₃₁. FIG. 2A shows separate supply nodes 292 associated with circuits 202₀ through 202₃₁. However, supply nodes 292 associated with circuits 202₀ through 202₃₁ can be the same node. Circuit paths L₀ through L₃₁ can be coupled between conductive pad 205 and respective nodes 215₀ through 215₃₁.

As shown in FIG. 2A, each of circuit paths L₀ through L₃₁ can include a single resistor (e.g., only one resistor) or multiple resistors. The multiple transistors can be parallel-connected transistors that are coupled between conductive pad 205 and a respective node among nodes 215₀ through 215₃₁. As shown in FIG. 2A, circuit path L₁ includes a single resistor R (only one instance of resistor R) coupled between conductive pad 205 and node 215₀. Circuit path L₂ includes a single resistor R (only one instance of resistor R) coupled between conductive pad 205 and node 215₂. Each of circuit path L₀ and circuit path L₃₁ can include parallel-connected resistors. As shown in FIG. 2A, circuit path L₀ includes parallel-connected resistors in that multiple resistor R (multiple instances of resistor R) of circuit path L₀ are coupled in parallel with each other between node 215₀ and conductive pad 205. Circuit path L₃₁ includes parallel-connected resistors in that multiple resistor R (multiple instances of resistor R) of circuit path L₃₂ are coupled in parallel with each other between node 215₃₁ and conductive pad 205.

In an example, as shown in FIG. 2B, circuit path L₀ can include 14 resistors R (14 instances of resistor R) coupled in parallel with each other between node 215₀ and conductive pad 205. In another example, as shown in FIG. 2C, circuit path L₃₁ can include 7 resistors R (7 instances of resistor R) coupled in parallel with each other between node 215₃₁ and conductive pad 205. The resistor quantity (the number of resistors R) in a circuit path can be the same as or different from the resistor quantity (the number of resistors R) in another circuit path. The value (in ohm units) of resistor R (a single resistor) among circuit paths L₀ through L₃₁ can be the same (e.g., is designed to have the same resistor structure). Resistors R of circuit paths L₀ through L₃₁ can form part of resistance R_{ON} or part of resistance R_{ODT} of driver 110. In FIG. 2A, resistors R are arranged in a non-binary weighted pattern, as described in more detail below.

As shown in FIG. 2A, circuits (e.g., logic circuits) 204₀ through 204₃₁ can have respective logic gate (e.g., NAND gate) 204A, logic gate (e.g., NOR gate) 204B, and an inverter 204C. Circuits 204₀ through 204₃₁ can operate to receive information (e.g., data information) D, Codeᵢ_P₀ through Codeᵢ_P₃₁ and Codeᵢ_N₀ through Codeᵢ_N₃₁. Codeᵢ_P₀ through Codeᵢ_P₃₁ in FIG. 2A can represent code Codeᵢ_P₀ through Codeᵢ_Pⱼ of FIG. 1. Codeᵢ_N₀ through Codeᵢ_N₃₁ in FIG. 2A can represent code Codeᵢ_N₀ through Codeᵢ_Nⱼ of FIG. 1.

In FIG. 2A, Codeᵢ_P₀ through Codeᵢ_P₃₁ and Codeᵢ_N₀ through Codeᵢ_N₃₁ can be configured (e.g., programmed) such that circuit paths L₀ through L₃₁ can provide resistance R_{ON} (e.g., during a transmitting mode) with a particular value (e.g., a selected value) or resistance R_{ODT} (e.g., during a receiving mode) with a particular value (e.g., a selected value). Codeᵢ_P₀ through Codeᵢ_P₃₁ and Codeᵢ_N₀ through Codeᵢ_N₃₁ can also be configured to control circuit 204₀ through 204₃₁, so that the value of information D provided from driver 110 to conductive pad 205 reflects (e.g., to be the same as) the value of information D provided on conductive line 120.

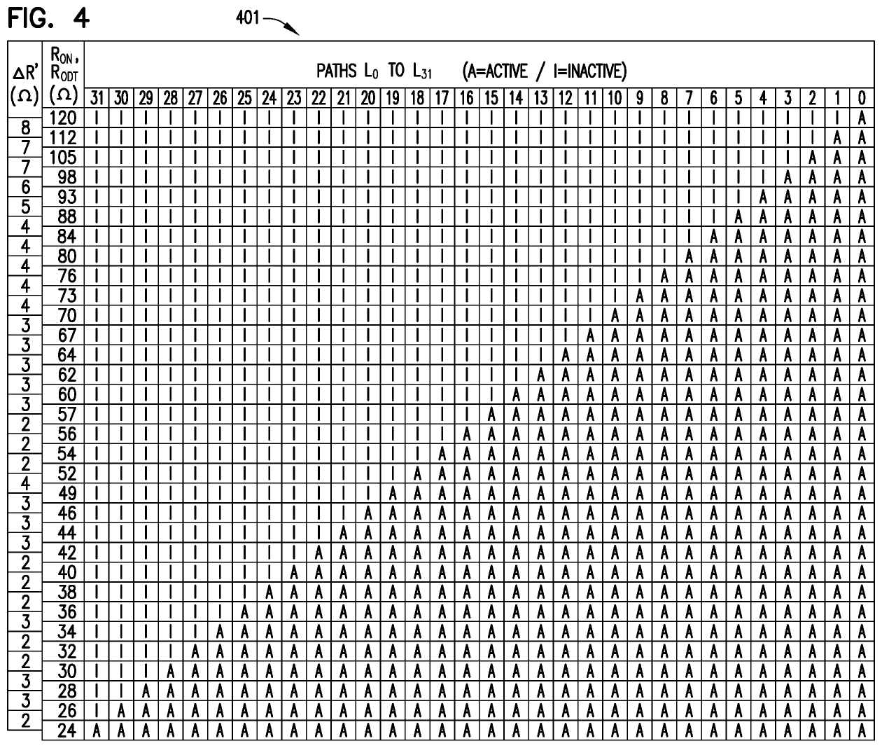

FIG. 3 shows a chart 301 illustrating an example of resistor quantity (the number of resistors) of resistor R in each circuit path among 32 circuit paths L₀ through L₃₁ of FIG. 2A, according to some embodiments described herein. The number of resistors R in chart 301 is an example. However, the resistor quantity of resistor R per circuit path of circuit path L₀ through L₃₁ can vary. As shown in FIG. 3, circuit path L₀ can include 14 resistors R (as shown in FIG. 2B). Each of circuit paths L₀ and L₁ can include a single resistor R (as shown in FIG. 2A). Other circuit paths L₂ through L₃₁ can include respective resistor quantities, as shown in chart 301.

As shown in FIG. 3, at least two of the circuit paths (e.g., circuit paths L₁ through L₁₆) include a single resistor. At least two of the circuit paths includes the same number of parallel-connected resistors. The circuit paths that include the same number of parallel-connected resistors can be adjacent circuit paths. For example, circuit paths L₁₇ through L₂₃ are adjacent circuit paths where each of circuit paths L₁₇ through L₂₃ includes 2 parallel-connected resistors. Circuit paths L₁₈ through L₂₆ are adjacent circuit paths where each of circuit paths Lis through L₂₆ includes 3 parallel-connected resistors. Circuit paths L₂₇ and L₂₈ are adjacent circuit paths where each of circuit paths L₂₇ and L₂₈ includes 4 parallel-connected resistors. Circuit paths L₂₉, L₃₀, and L₃₁ are adjacent circuit paths where circuit paths L₂₉, L₃₀, and L₃₁ include 4 parallel-connected resistors, 6 parallel-connected resistors, and 7 parallel-connected resistors, respectively. As shown in FIG. 3, at least three adjacent circuit paths of the circuit paths include a single resistor. For example, circuit paths L₁ through L₁₆ are adjacent circuit paths (circuit paths located next to each other) that include a single resistor in each of circuit paths L₁ through L₁₆.

As shown in FIG. 3, two adjacent circuit paths can have different number of resistors. For example, circuit paths L₀ and L₁ are adjacent circuit paths where circuit path L₀ includes 14 resistors and circuit path L₁ includes 1 resistor. Circuit paths L₁₆ and L₁₇ are adjacent circuit paths where circuit path L₁₆ includes 1 resistor and circuit path L₁₇ includes 2 resistors. Circuit paths L₂₃ and L₂₄ are adjacent circuit paths where circuit path L₂₃ includes 2 resistors and circuit path L₂₄ includes 3 resistors. Adjacent circuit's paths L₂₆ and L₂₇ and adjacent circuit's paths L₂₈ through L₃₁ also have different number of resistors as shown in FIG. 3.

The resistors (resistors R in FIG. 2A) of circuit paths L₀ through L₃₁ (shown in FIG. 2A and listed in FIG. 3) are arranged in a non-binary weighted pattern. Conventional circuits that have a binary weighted pattern may include resistors arranged in a pattern of R, R/2, R/4, R/8 and so on (or alternatively a pattern of R, 2R, 4R, 8R and so on) in consecutive circuits (from one circuit to the next circuit (adjacent circuit). In this example, the term “R” represents base resistance value (e.g., a unit resistance value). As described above (in the background section), the profile of an entire resistance range provided resistors arranged in a binary weighted pattern often exhibit significant nonlinearity. Such nonlinearity can have drawbacks, as described above.

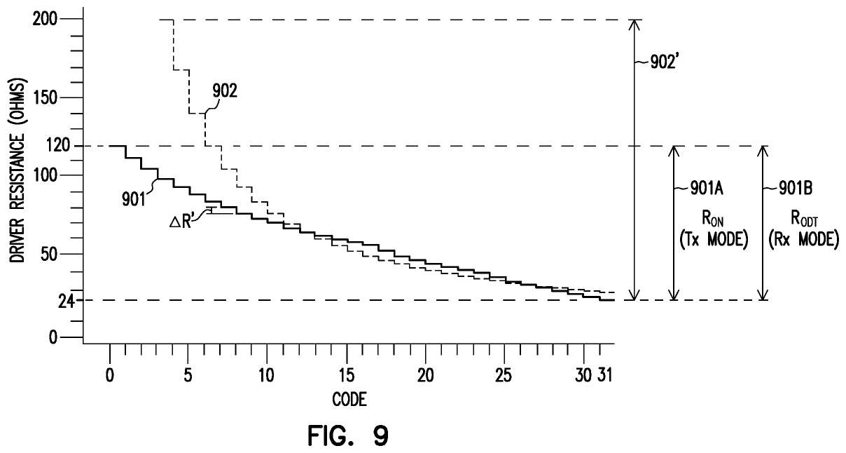

In FIG. 2A, resistors R of circuit paths L₀ through L₃₁ are arranged (e.g., structured) in a non-binary weighted pattern. For example, as shown in chart 301 of FIG. 3, resistors R of circuit paths L₀ through L₃₁ are arranged (e.g., structured) in a non-binary weighted pattern in that the resistance values of circuit paths L₀ through L₃₁ do not follow a binary weighted pattern of R, R/2, R/4, R/8 and so on, or other binary weighted patterns. Improvement and benefits of using circuit paths L₀ through L₃₁ having resistors (e.g., resistors R) arranged in a non-binary weighted pattern to provide resistance R_{ON} or resistance R_{ODT} is described in more detail below with reference to FIG. 9.

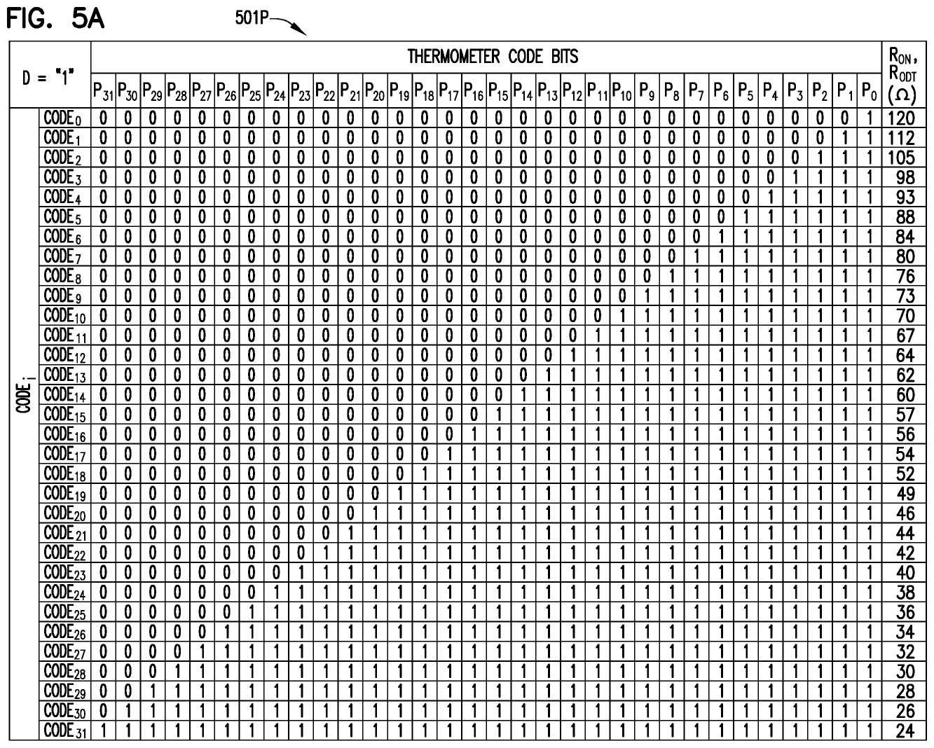

FIG. 4 shows a chart 401 illustrating resistances (e.g., 32 selectable resistances) of the resistance range (e.g., 24 ohms though 120 ohms) of driver of FIG. 2A in which the resistances can be selected by selectively activating and deactivating circuit paths L₀ through L₃₁ the driver 110, according to some embodiments described herein. As shown in FIG. 4, resistance range from 24 ohms to 120 ohms can include 32 resistance values, such as 24 ohms, 26 ohms, and so on up to 120 ohms. The 32 resistances are selectable resistances. One of the 32 resistance values can be selected (e.g., based on specification for device 101) to be resistance R_{ON} (e.g., during a transmitting mode of device 101) or resistance R_{ODT} (e.g., during a receiving mode of device 101). Chart 401 also shows which circuit path (or circuit paths) among circuit paths L₀ through L₃₁ can be activated (indicted by label “A”) or deactivated (inactivated, as indicated by label “I”) to select a particular resistance value (among the 32 resistance values) to be resistance R_{ON} or resistance R_{ODT}. Activating a particular circuit path (among circuit paths L₀ through L₃₁) includes turning on a respective transistor (one of transistors P₀ through P₃₁ or one of transistor N₀ through N₃) to form a conductive path between conductive pad 205 (FIG. 2A) and either supply node 291 or supply node 292 through that particular circuit path (the activated circuit path). The activated circuit path includes a respective transistor (which is turned-on) among transistors P₀ through P₃₁ or transistors N₀ through N₃₁ and a circuit path (one of circuit paths L₀ through L₃₁) coupled to the respective transistor. Deactivating a particular circuit path (among circuit paths L₀ through L₃₁) includes not forming a conductive path between conductive pad 205 (FIG. 2A) and either supply node 291 or supply node 292. Deactivating a particular circuit path (not to form a particular circuit path) includes turning off a respective transistor (one of transistors P₀ through P₃₁ or one of transistor N₀ through N₃), so that a conductive path is not formed between conductive pad 205 (FIG. 2A) and either supply node 291 or supply node 292 through that respective transistor (the turned-off transistor) and a circuit path (one of circuit paths L₀ through L₃₁) coupled to the respective transistor (the turned-off transistor).

As shown in chart 401, for example, to select a resistance value of 120 ohms (to be the selected value for resistance R_{ON} or resistance R_{ODT}), circuit path L₀ (selected circuit path or activated circuit path) can be activated (indicated by label “A”) and circuit paths L₁ through L₃₁ can be deactivated or inactivated (indicated by label “I”). In another example, to select a resistance value of 112 ohms (to be the selected value for resistance R_{ON} or resistance R_{ODT}), circuit paths L₀ and L₁ (selected circuit paths or activated circuit paths) can be activated (indicated by label “A”) and circuit paths L₂ through L₃₁ can be deactivated or inactivated (indicated by label “I”). In another example, to select a resistance value of 30 ohms (to be the selected value for resistance R_{ON} or resistance R_{ODT}), circuit paths L₀ through L₂₈ (selected circuit paths or activated circuit paths) can be activated (indicated by label “A”) and circuit paths L₂₉, L₃₀ and L₃₁ can be deactivated or inactivated (indicated by label “I”). Thus, based on chart 401, a selected value for resistance R_{ON} or resistance R_{ODT} can be obtained by selectively activating and deactivating circuit paths L₀ through L₃₁ of driver 110.

Chart 401 also shows a value ΔR′ (delta R′ value) that indicates a difference between two adjacent (two consecutive) resistance values. In an example, the resistance values (24 ohms to 120 ohms) in chart 401 can be calculated based on a target ΔR value (a known delta R value). The ΔR′ values in chart 401 can be used to determine whether a majority of the ΔR′ values is within the target ΔR value with an acceptable margin.

The following description describes an example of a procedure to find a quantity of resistors each of circuit paths L₀ through L₃₁ of driver 110, so that driver 110 (FIG. 2A) can provide a resistance range (e.g., from 24 ohms to 120 ohms shown in chart 401 of FIG. 4) for resistance R_{ON} and resistance R_{ODT}.

The procedure can include determining the resistance value of a single resistance R (e.g., one unit resistance building block), such as resistance R shown in FIG. 2A. Then, the instance of resistance R can be repeated multiple times to build circuit paths (e.g., circuit paths L₀ through L₃₁) for driver 110, such that the circuit paths can provide a resistance range (e.g., from 24 ohms to 120 ohms as shown in FIG. 4). The resistance range (e.g., a predetermined resistance range) can be based on specifications. For simplicity, the resistance value of resistance R (e.g., one unit resistance building block) used in the calculation below can include (e.g., can be assumed to be) a resistance between conductive pad 205 (FIG. 2A) and supply node 291 through a transistor among one of transistors P₀ through P₃₁ under a typical structure of the transistor and operating condition of device 101.

After the resistance value of resistance R is determined, the procedure can continue to determine the quantity of resistance R (the number of resistance R) coupled in parallel in a circuit path (e.g., circuit path L₀) of driver 110 providing a maximum resistance value R_{MAX} (e.g., 120 ohms) of the resistance range. This quantity can be based on the following Equation (1)

n=floor(R/R_{MAX}) (1)

In the above equation the term n represents the quantity of parallel connected resistor R to provide the maximum resistance value R_{MAX} (e.g., 120 ohms). The calculation herein uses an example where resistance value of resistance R is 1680 ohms (R=1680 ohms). Thus, based on Equation (1), n=floor (1680/120)=14. In this example, as shown in FIG. 2B, 14 instances of resistor R can be coupled in parallel (between node 215₀ can conductive pad 205 in FIG. 2A) to provide the maximum resistance value R_{MAX} of 120 ohms.

The procedure can continue with calculating resistance value (Rn+1) of the circuit path (e.g., circuit path L₁) next to the circuit path (e.g., circuit path L₀) associated with the least significant bit (LSB) of the encoding scheme, such that (Rn+1//Rn)=Rn−ΔR. In this equation, Rn+1 and Rn represent the resistance values of next circuit path (e.g., circuit path L₁) and the circuit path (e.g., circuit path L₀) associated with the LSB of the encoding scheme. The value ΔR (delta R) is a known value (e.g., based on specification) that represents a target difference in resistance value between two consecutive resistance values associated with two consecutive values of code information of the encoding scheme. As an example, the ΔR value in the procedure described here is assumed to be 3 ohms (e.g., ΔR=3 ohms).

To determine the number resistance R for the next circuit path (mentioned above), Rn+1 in the above equation can be expressed in terms of n-instances of resistance R. Then based on Equation (1) above, the quantity (n) of resistor R for the next circuit path (e.g., circuit path L₁) can be obtained based on Equation (2) below.

n=floor[(R/(Rn−ΔR)] (2)

From Equation (2), n=floor [(1680/(1680−3)=1. Thus, as shown in FIG. 2B, one instance of resistor R can be included in circuit path L₁.

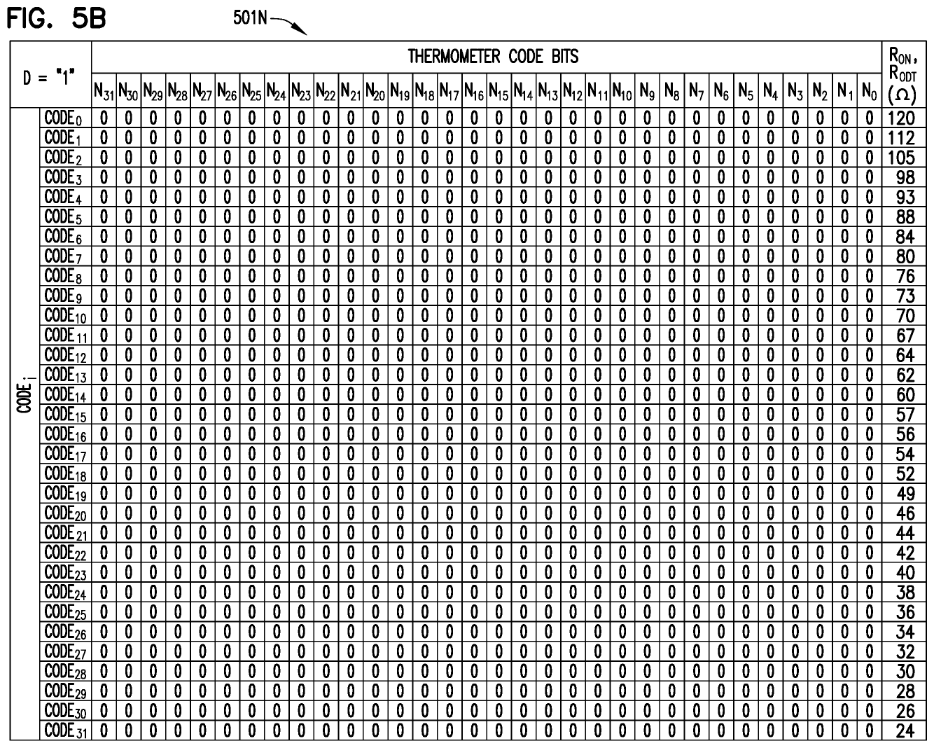

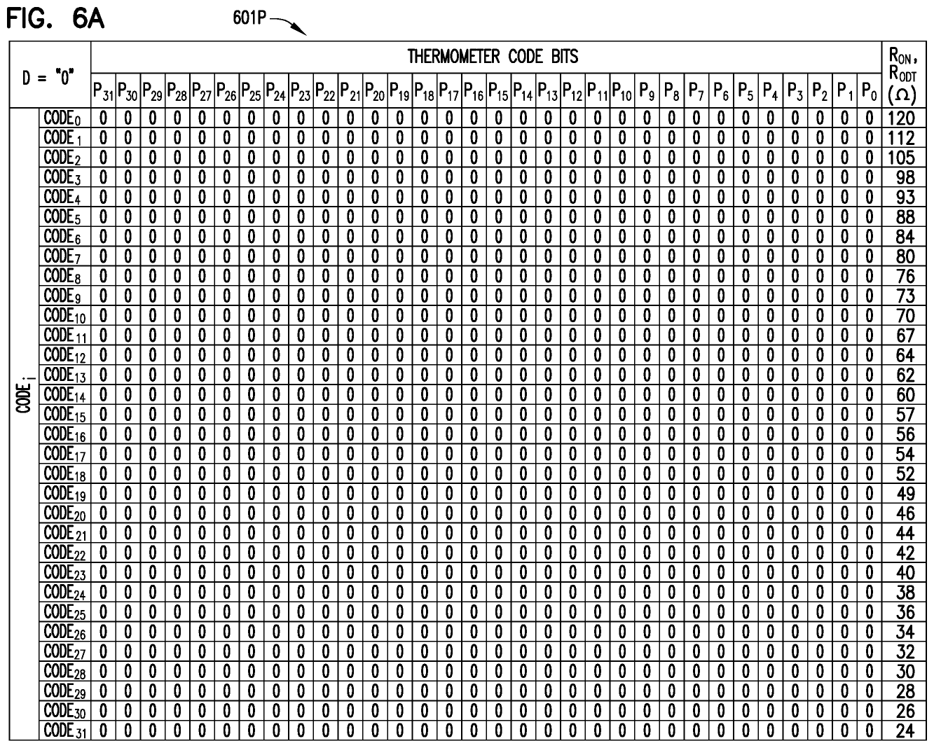

The procedure above can be repeated using Equation (2) until the minimum resistance value R_{MIN} (e.g., 24 ohms) is obtained. The number of times (e.g., steps) used to obtain the resistance range (e.g., 24 ohms to 120 ohms) can be used to determine the number of encoding bits of code information (e.g., binary code information). For example, as shown in FIG. 4, 32 steps may be performed to obtain the resistance range. Thus, in this example, a binary code information having 5 binary bits can be used to encode 32 resistance values of the resistance. The binary code information (having 5 binary bits) can be converted into thermometer code information (e.g., 32 thermometer bits based on the 5 binary bits). The thermometer code information (e.g., 32 thermometer bits) can be used to selectively activate or deactivate circuit paths L₀ through L₃₁ to select a value for resistance R_{ON} or resistance R_{ODT}, as described in more detail with FIG. 5A through FIG. 6B.

Based on the procedure described above for structuring (e.g., forming) resistors in respective circuit paths L₀ through L₃₁ (FIG. FIG. 2A) of driver 110, circuit path L₀ can be associated with the LSB and circuit path L₃₁ can be associated with the most significant bit (MSB) in an encoding scheme. For example, a lower value of binary code information (e.g., binary code information before conversion to thermometer code information) can be used to encode (e.g., used to be associated with) a higher resistance of the resistance range. A higher value of the binary code information can be used to encode (e.g., used to be associated with) a lower resistance of the resistance range. Thus, in this encoding scheme, the relationship between the values of code information (e.g., binary code information) and the resistance values of the resistance range is reversely proportional to each other. For example, an increase in the value of the code information (e.g., binary code information) is associated with a decrease in resistance value. A decrease in the value of the code information (e.g., binary code information) is associated with an increase in resistance value.

Moreover, based on the procedure described above as shown in chart 301, circuit path L₀ (associated with LSB position of the binary code information) can have a largest number (highest quantity) of resistors (e.g., 14 parallel-connected transistor). Circuit path L₃₁ (associated with MSB position of the binary code information) can have 7 resistors, which is fewer than the number of resistors (e.g., 14 resistors) of circuit path L₀. Thus, the size (physical size) of circuit path L₀ at the LSB position can be larger than the size of circuit path L₃₁ at the MSB position. Moreover, based on chart 301 in FIG. 3, circuit path L₀ can have the largest physical size (e.g., based on the number of resistors R) among the circuit paths of driver 110. Thus, driver 110 can have its physically largest circuit path (e.g., circuit path L₀) in the LSB location, tuned to the highest specified resistance (e.g., R_{MAX}). Consequently, all other resistances associated with circuit paths at other significant bit position (e.g., more significant bit [mSB]) are non-dominant resistances. This means that for driver 100 (e.g., a linear driver), reasonable and discrete deviations from the computed ideal values of the circuit paths at the non-dominant mSB positions do not affect ΔR significantly.

FIG. 5A and FIG. 5B show charts 501P and 501N, respectively, illustrating an encoding scheme that uses thermometer bits to encode the resistances of the resistance range of the driver of FIG. 2A when information D has a value corresponding to logic one (e.g., D=“1”), according to some embodiments described herein. In FIG. 5A and FIG. 5B, Codeᵢ are thermometer codes. FIG. 5A and FIG. 5B show 32 thermometer codes (Code₀ through Code₃₁) based on the number 32 circuit paths 202₀ through 202₃₁ of driver 110 used to provide a resistance range (e.g., 24 ohms to 120 ohms). The 32 Code₀ through Code₃₁ can be used to select 32 respective resistance values 24 ohms through 120 ohms.

The value of each of Code₀ through Code₃₁ in FIG. 5A is a combination of 32 thermometer bits presented by bits P₀ through P₃₁ in FIG. 5A. Bits P₀ through P₃₁ are the same as bits P₀ through P₃₁ provide to respective input nodes of respective logic gates 204A in FIG. 2A. The value of each of Code₀ through Code₃₁ in FIG. 5B (which have values different from Code₀ through Code₃₁ in FIG. 5A) is a combination of 32 thermometer bits presented by bits N₀ through N₃₁ in FIG. 5A. Bits N₀ through N₃₁ in FIG. 5B are the same as bits N₀ through N₃₁ provide to respective input nodes of respective logic gates 204B in FIG. 2A. Based on chart 501P and 501N, when information D has a value corresponding to logic one, the resistance value (selected to be resistance R_{ON} or resistance value R_{ODT}) can be selected.

For example, Code₀ in FIG. 5A and FIG. 5B can be used if the resistance value 120 ohms is selected. In this example, the value of code information (e.g., thermometer bits) represented by Codeᵢ-P₀ through Codeᵢ-P₃₁ in FIG. 2A correspond to the value of Code₀ associated with bits P₀ through P₃₁ (32 thermometer bits) in FIG. 5A. As shown in FIG. 5A, Code₀ associated with bits P₀ through P₃₁ includes P₀=1 (logic one) and P₂ through P₃₁=0 (logic zero). Thus, in FIG. 2A in this example (Codeᵢ=Code₀), the values of 32 thermometer bits (bits P₀ through P₃₁) can include Codeᵢ-P₀=1, Codeᵢ-P₁=0, Codeᵢ-P₂=0, and Codeᵢ-P₃ (not shown in FIG. 2A) through Codeᵢ-P₃₁=0. In this example (where 120 ohms is selected), the value of Codeᵢ-N₀ through Codeᵢ-N₃₁ in FIG. 2A correspond to the value of Code₀ in FIG. 5B. As shown in FIG. 5B, Code₀ includes 32 thermometer bits (N₀ through N₃₁) where N₀ through N₃₁=0 (logic zero). In this example, in FIG. 2A, Codeᵢ-N₀ through Codeᵢ-N₃₁=0.

In another example, Code₂₈ in FIG. 5A and FIG. 5B can be used if the resistance value 30 ohms is selected. In this example, the value of code information (e.g., thermometer bits) represented by Codeᵢ-P₀ through Codeᵢ-P₃₁ in FIG. 2A correspond to the value of Code₂₈ associated with bits P₀ through P₃₁ (32 thermometer bits) in FIG. 5A. As shown in FIG. 5A, Code₂₈ associated with bits P₀ through P₃₁ includes P₀ through P₂₈=1 (logic one) and P₂₉ through P₃₁=0 (logic zero). Thus, in FIG. 2A in this example (Codeᵢ=Code₂₈), Codeᵢ-P₀=1, Codeᵢ-P₁=1, Codeᵢ-P₂=1, Codeᵢ-P₃ through Codeᵢ-P₂₈ (not shown in FIG. 2A)=1, and Codeᵢ-P₂₉ through Codeᵢ-P₃₁=0. In this example (where 30 ohms is selected), the value Codeᵢ-N₀ through Codeᵢ-N₃₁ in FIG. 2A correspond to the value of Code₀ in FIG. 5B. As shown in FIG. 5B, Code₂₈ includes 32 thermometer bits (N₀ through N₃₁) where N₀ through N₃₁=0 (logic zero). Thus, in FIG. 2A in this example, Codeᵢ-N₀ through Codeᵢ-N₃₁=0.

FIG. 6A and FIG. 6B show charts 601P and 601N, respectively, illustrating an encoding scheme that uses thermometer bits to encode the resistances of the resistance range of the driver of FIG. 2A when information D has a value correspond to logic zero (e.g., D=“0”), according to some embodiments described herein. Charts 601P and 601N include similar information like charts 501P and 501N (FIG. 5A and FIG. 5B) such as code information (e.g., Codeᵢ has 32 codes Code₀ through Code₃₁) and the values (logic one or logic zero) of thermometer bits (P₀ through P₃₁ and N₀ through N₃₁) for selecting a resistance value among a resistance range. However, charts 601P and 601N are used when information D has a value corresponding to logic zero (instead of logic one). The resistance value (selected to be resistance R_{ON} or resistance value R_{ODT}) can be selected in ways similar to that of FIG. 5A and FIG. 5B.

For example, Code₂₈ in FIG. 6A and FIG. 6B can be used if the resistance value 30 ohms is selected. In this example, the value Codeᵢ-P₀ through Codeᵢ-P₃₁ in FIG. 2A correspond to the value of Code₀ associated with bits P₀ through P₃₁ in FIG. 6A. As shown in FIG. 6A, Code₂₈ associated with bits P₀ through P₃₁ includes P₀ through P₃₁=0 (logic zero). Thus, in FIG. 2A in this example, Codeᵢ-P₀ through Codeᵢ-P₃₁=0. In this example (where 30 ohms is selected), the value Codeᵢ-N₀ through Codeᵢ-N₃₁ in FIG. 2A correspond to the value of Code₂₈ associated with bits N₀ through N₃₁ in FIG. 6B. As shown in FIG. 6B, Code₂₈ associated with bits N₀ through N₃₁ includes N₀ through N₂₈=1 (logic one) and N₂₉ through N₃₁=0 (logic zero). Thus, in FIG. 2A in this example (Codeᵢ=Code₂₈), Codeᵢ-N₀=1, Codeᵢ-N₁=1, Codeᵢ-N₂=1, Codeᵢ-N₃ through Codeᵢ-N₂₈ (not shown in FIG. 2A)=1, and Codeᵢ-N₂₉ through Codeᵢ-N₃₁=0.

As described above with reference to FIG. 1, device 101 can include a binary-to-thermometer converter to convert the value of binary code information having binary bits into a thermometer code information having thermometer bits. For example, 5 bits of the binary code information associated with the selected 30 ohms can be converted into thermometer code information having 32 thermometer bits. The 32 thermometer bits having respective values (e.g., “1” or “0”) can be represented by bits P₀ through P₃₁ and bits N₀ through N₃₁, as shown in FIG. 5A, FIG. 5B, FIG. 6A, and FIG. 6B. The thermometer bits of the thermometer code information can be used to selectively active or deactivate circuit paths to select resistance R_{ON} or resistance R_{ODT} as described above.

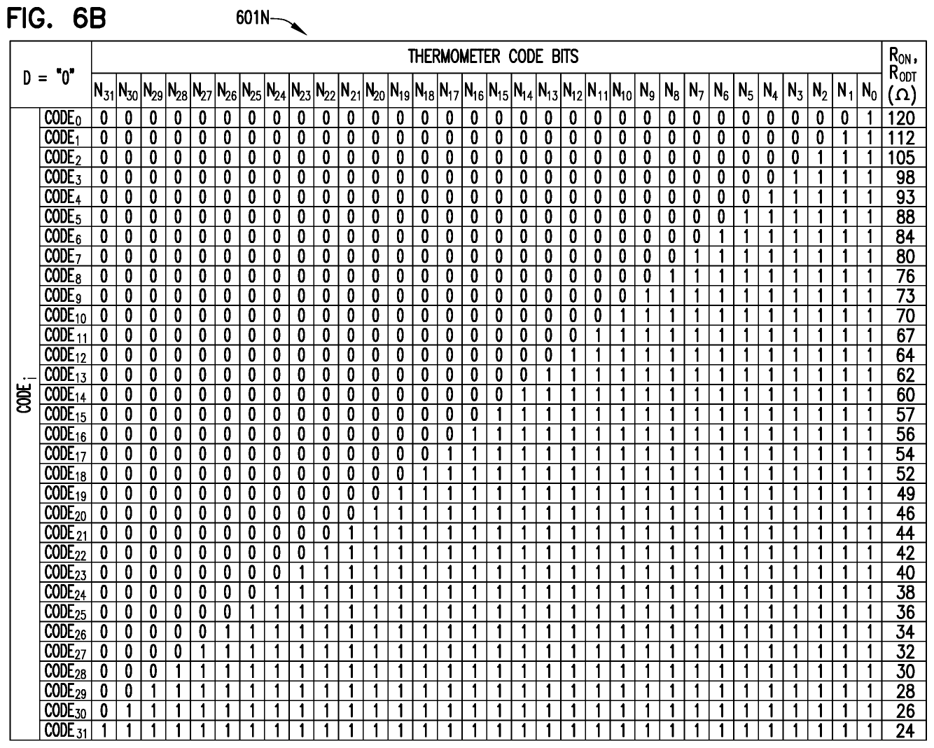

FIG. 7 shows a chart 701 illustrating an example of resistor quantity of resistor R in selected circuit path among 32 circuit paths L₀ through L₃₁ of FIG. 2A to provide an extended resistance range for a resistance R_{ODT-X} (extended termination resistance), according to some embodiments described herein. Resistance R_{ODT-X} associated with FIG. 7 can be used as termination resistance (e.g., during a receiving mode) like resistance R_{ODT}. However, the resistance range (e.g., from 120 ohms to 240 ohms) for resistance R_{ODT-X} can be different from the resistance range (e.g., 24 ohms to 120 ohms) for resistance R_{ODT}. Thus, resistance R_{ODT-X} can be used to provide a relatively high termination resistance (e.g., from 120 ohms to 240 ohms).

To obtain a resistance range (e.g., 120 ohms to 200 ohms), the resistor quantity (the number of resistors R) in circuit paths L₀ through L₃₁ (FIG. 2A) can be calculated based on the procedure described above and Equations (1) and (2). As shown in FIG. 7, circuit paths L₀ through L₇ can be a single resistor R like the single resistor R in circuit paths L₀ through L₇ of chart 301 (used to resistance R_{ODT}). However, as shown in FIG. 7, circuit path L₀ can have 7 instances of parallel connected resistor R. As a comparison, circuit path L₀ in chart 301 have 14 instances of parallel connected resistor R. The value for resistance R can be the same (e.g., 1, 680 ohms) in charts 301 and 701. Thus, if resistance R_{ODT-X} is selected as the termination resistance, then, 14 instances of resistor R circuit path L₀ (used during a transmitting mode) can be configured, such that, in a receiving mode, only 7 of the 14 resistors can be used (the remaining 7 resistor R can be disconnected [unused]) or disabled. Then, during a transmitting mode, 14 instances of resistor R circuit path L₀ can be used again to provide a resistance range of 24 ohms to 120 ohms based on chart 301.

Device 101 (FIG. 1) can be configured (e.g., programmed) to select resistance R_{ON}, resistance R_{ODT}, or resistance R_{ODT-X} based on a particular mode of device 101. For example, device 101 can include circuitry to store control information (e.g., control information) that indicate whether the mode is a transmitting mode or a receiving mode. The control information can include a single control bit (e.g., a mode indicator bit), such that one value (e.g., logic one) of the control bit can be used to indicate a transmitting mode, and another value (e.g., logic zero) of the control bit can be used to indicate a receiving mode. As described above, device 101 can change (e.g., switch) between a transmitting mode and a receiving mode by changing the value of control information (e.g., by changing the value of the control bit between logic one and logic zero). During the receiving mode, the value of termination resistance can be based on the value of either resistance R_{ODT} or resistance R_{ODT-X}, depending on which of resistance R_{ODT} and resistance R_{ODT-X} is selected to be termination resistance.

Thus, as described above with reference to FIG. 2A through FIG. 7, resistors R of circuit paths L₀ through L₃₁ can be structured to provide either resistance range (e.g., 24 ohms to 120 ohms) for resistance R_{ODT} or resistance range (e.g., 120 ohms to 240 ohms) for resistance R_{ODT-X}.

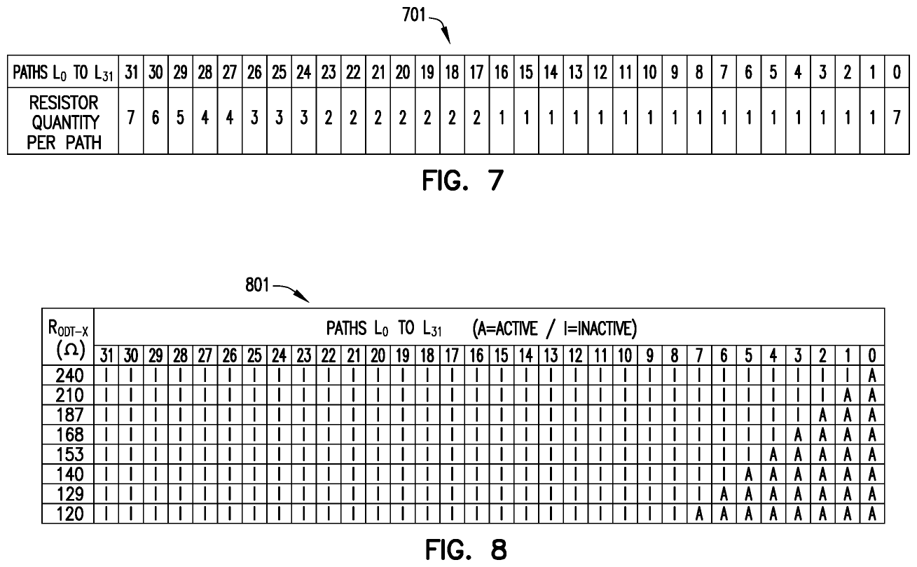

FIG. 8 shows a chart 801 illustrating resistances (e.g., 8 selectable resistances) of a resistance range from 120 ohms to 240 ohms associated with FIG. 7 in which the resistances can be selected by selectively activating and deactivating circuit paths L₀ through L₃₁ of driver 110, according to some embodiments described herein. As shown in FIG. 8, resistance range from 120 ohms to 240 ohms can include 7 resistance values, such as 120, 129, 140, and so on up to 240 ohms. The 7 resistances are selectable resistances. One of the 7 resistance values can be selected (e.g., based on specification for device 101) to be resistance R_{ODT-X}. Chart 801 also shows which circuit path (or circuit paths) among circuit paths L₀ through L₃₁ can be activated (indicted by label “A”) or deactivated (inactivated, as indicated by label “I”) to select a particular resistance value (among the 7 resistance values) to be resistance R_{ODT-T}.

For example, to select a resistance value of 240 ohms (to be the selected value for resistance R_{ODT-X}), circuit path L₀ can be activated (indicated by label “A”) and circuit paths L₀ through L₃₁ can be deactivated or inactivated (indicated by label “I”). In another example, to select a resistance value of 153 ohms (to be the selected value for resistance R_{ODT-X}), circuit paths L₀ through L₄ can be activated (indicated by label “A”) and circuit paths L₅ through L₇ can be deactivated or inactivated (indicated by label “I”). Thus, based on chart 401, a selected value for resistance R_{ODT-X} can be obtained by selectively activating and deactivating circuit paths L₀ through L₃₁ of driver 110.

FIG. 9 is a graph showing relationship between code information CODE and a resistance range provided by driver 110 of FIG. 2A, according to some embodiments described herein. In FIG. 9 shows and example of 32 values (0 through 31 values) of code information CODE, which can be binary code having a number of binary bits. In FIG. 9, code information CODE can include 5 binary bits (to provide 32 possible binary combinations) to represent the 32 values of code information CODE. FIG. 9 shows a resistance range 901A for resistance R_{ON}, and a resistance range 901B for resistance R_{ODT}. As shown in FIG. 9, resistance ranges 901A and 901B can be the same resistance range (from 24 ohms to 120 ohms). Resistance R_{ON}, resistance R_{ODT}, and resistance range from 24 ohms to 120 ohms are described above with reference to FIG. 2A through FIG. 6B. For example, the resistance value for resistance R_{ON} (e.g., associated with a transmitting mode) can be selected from resistance range 901A. The resistance value for resistance R_{ODT} (e.g., associated with a receiving mode) can be selected from resistance range 901B (which is the same as resistance range 901).

In the example shown in FIG. 9, resistance range 901A (which is the same as resistance range 901B) includes 32 resistances (resistance values) 901. In FIG. 9, ΔR′ value (delta R′ value) can correspond to ΔR′ values described above with reference to FIG. 9. As shown in FIG. 9, value ΔR′ is a difference (an increase or a decrease in resistance value) between two adjacent (two consecutive) resistance values.

As shown in FIG. 9, the relationship between the values of code information CODE and the resistance values of resistance range 901A or 901B is inversely proportional to each other. For example, as the values of code information CODE increase from a lower value to higher value (e.g., change in a direction from 0 to 31), the resistance values of resistance range 901A or 901B decrease from a higher value to a lower value (e.g., change in a direction from 120 ohms to 24 ohms). Thus, a lower value and a higher value of the 5 binary bits of code information CODE can be associated with (e.g., can be used to select) a higher resistance and a lower resistance, respectively, of the resistance range 901A or 901B.

FIG. 9 also show resistances (resistance values) 902 of a resistance range 902′. Resistance range 902′ can be provided by a conventional binary weighted output driver. As shown in FIG. 9, resistance values 902′ exhibits significant nonlinearity relative to resistances 901. In resistance range 902′, a small sub-range (e.g., between 20 ohms to 50 ohms) may meet the specifications for a certain target ΔR value and unit change (e.g., an increase) in the value of the code information. However, this can cause the conventional binary weighted driver to use a relatively large number of binary bits for a given resistance range (e.g., minimum resistance R_{MIN} and maximum resistance R_{MAX}) to be within a target ΔR value.

In contrast, as shown in FIG. 9, graph 901 exhibits linearity profile in the resistance range (e.g., resistance range 901A or 901i). This linearity is resulted from the non-binary weighted pattern of resistors R of circuit paths L₀ through L₃₁ (FIG. 2A and FIG. 3). In comparison with some conventional drivers (e.g., drivers having resistors arranged in a binary weighted pattern), driver 110 (which include resistors arranged in a non-binary weighted pattern) includes the following improvements and benefits. Since the entire resistance range exhibits linearity, fewer resistors (e.g., resistors R in FIG. 2A) can be used in driver to provide useful resistance range for a given resistance range and delta R. Thus, the size of driver 110 can be relatively smaller than that of a conventional driver. In cases where driver 110 has a size similar to the size of the conventional driver, driver 110 can provide a larger usable resistance range. Since the entire resistance range is usable and exhibits linearity profile, reduced search time associated with selecting the resistance for the driver (e.g., driver 110) can be achieve. Further, using a thermometer code (e.g., thermometer bits) in driver 110 (as described above) allows on-the-fly updates associated with driver resistance to be more feasible. Moreover, arranging the resistors of driver 100 in a non-binary weighed patter, as described above, allow the same resistors (e.g., resistor bank) to be used for providing a resistance range for different types of conductive pads (e.g., data, command, address, control, and clock).

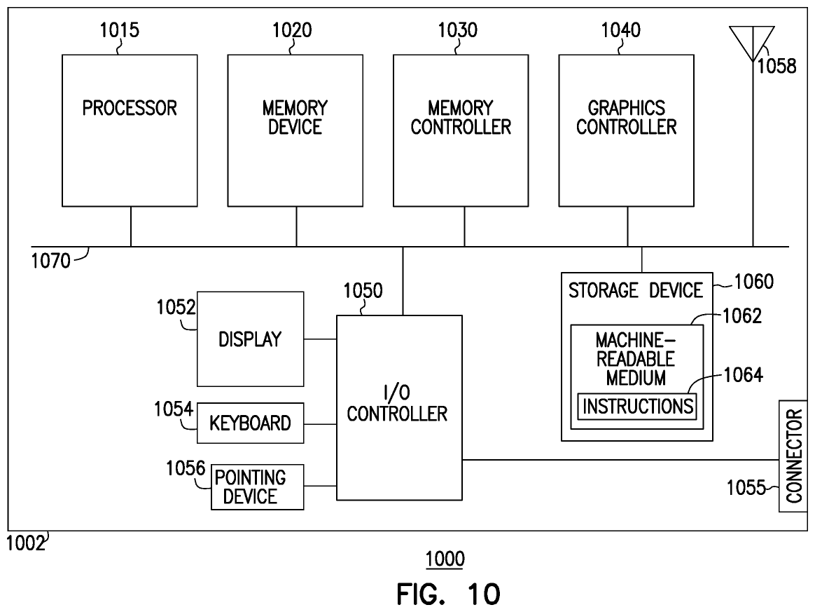

FIG. 10 shows an apparatus in the form of a system (e.g., electronic system) 1000, according to some embodiments described herein. System 1000 can be viewed as a machine. System (e.g., machine) 1000 can include or be included in a computer, a cellular phone, or other electronic systems. As shown in FIG. 10, system 1000 can include components (e.g., devices) located on a circuit board (e.g., PCB) 1002. The components can include a processor (e.g., a hardware processor) 1015, a memory device 1020, a memory controller 1030, a graphics controller 1040, an I/O controller 1050, a display 1052, a keyboard 1054, a pointing device 1056, at least one antenna 1058, a storage device 1060, and a bus 1070. Bus 1070 can include conductive lines (e.g., metal-based traces on a circuit board 1002 where the components of system 1000 are located).

System 1000 may be configured to perform one or more of the methods and/or operations described herein. At least one of the components of system 1000 (e.g., at least one of processor 1015, memory device 1020, memory controller 1030, graphics controller 1040, and I/O controller 1050) can include a device (e.g., device 101) described herein in which the device can include driver 110 and associated circuitry, as described above with reference to FIG. 2A through FIG. 9).

In FIG. 10, processor 1015 can include a general-purpose processor or an application specific integrated circuit (ASIC). Processor 1015 can include a central processing unit (CPU) and processing circuitry. Graphics controller 1040 can include a graphics processing unit (GPU) and processing circuitry. Memory device 1020 can include a dynamic random-access memory (DRAM) device, a static random-access memory (SRAM) device, a flash memory device, phase change memory, or a combination of these memory devices, or other types of memory. FIG. 10 shows an example where memory device 1020 is a stand-alone memory device separated from processor 1015. In an alternative structure, memory device 1020 and processor 1015 can be located on the same integrated circuit (IC) chip (e.g., a semiconductor die or IC die). In such an alternative structure, memory device 1020 is an embedded memory in processor 1015, such as embedded DRAM (eDRAM), embedded SRAM (eSRAM), embedded flash memory, or another type of embedded memory.

Storage device 1060 can include drive unit (e.g., hard disk drive (HID), solid-state drive (SSD), or another mass storage device). Storage device 1060 can include a machine-readable medium 1062 and processing circuitry. Machine-readable medium 1062 can store one or more sets of data structures or instructions 1064 (e.g., software) embodying or used by any one or more of the techniques or functions described herein. Instructions 1064 may also reside, completely or at least partially, within memory device 1020, memory controller 1030, processor 1015, or graphics controller 1040 during execution thereof by system (e.g., machine) 1000.

In an example, one of (or any combination of) processor 1015, memory 1020, memory controller 1030, graphics controller 1040, and storage device 1060 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 10 shows machine-readable medium 1062 as a single medium as an example. However, the term “machine-readable medium” may include a single medium or multiple media (e.g., a centralized or distributed database, and/or associated caches and servers) configured to store instructions 1064. Further, the term “machine-readable medium” may include any medium that is capable of storing, encoding, or carrying instructions for execution by system 1000 and that causes system 1000 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 1052 can include a liquid crystal display (LCD), a touchscreen (e.g., capacitive or resistive touchscreen), or another type of display. Pointing device 1056 can include a mouse, a stylus, or another type of pointing device. In some structures, system 1000 does not have to include a display. Thus, in such structures, display 1052 can be omitted from system 1000.

Antenna 1058 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 1000 does not have to include an antenna. Thus, in such structures, antenna 1058 can be omitted from system 1000.

I/O controller 1050 can include a communication module for wired or wireless communication (e.g., communication through one or more antennas 1058). Such wireless communication may include communication in accordance with WiFi communication technique, Long Term Evolution Advanced (LTE-A) communication technique, or other communication techniques.

I/O controller 1050 can also include a module to allow system 1000 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 1055 can include terminals (e.g., pins) to allow system 1000 to receive a connection (e.g., an electrical connection) from an external device (or system). This may allow system 1000 to communicate (e.g., exchange information) with such a device (or system) through connector 1055. Connector 1055 and at least a portion of bus 1070 can include conductive lines that conform with at least one of USB, DP, HDMI, Thunderbolt, PCIe, Ethernet, and other specifications.

FIG. 10 shows the components (e.g., devices) of system 1000 arranged separately from each other as an example. For example, each of processor 1015, memory device 1020, memory controller 1030, graphics controller 1040, and I/O controller 1050 can be included in (e.g., formed in or formed on) a separate integrated circuit (IC) chip (e.g., separate semiconductor die or separate IC die). In some structures of system 1000, two or more components (e.g., processor 1015, memory device 1020, graphics controller 1040, and I/O controller 1050) of system 1000 can be included in (e.g., formed in or formed on) the same IC chip (e.g., same semiconductor die), forming a SoC. Alternatively, two or more components (e.g., processor 1015, memory device 1020, graphics controller 1040, and I/O controller 1050) of system 1000 can be included in the same package a SiP.

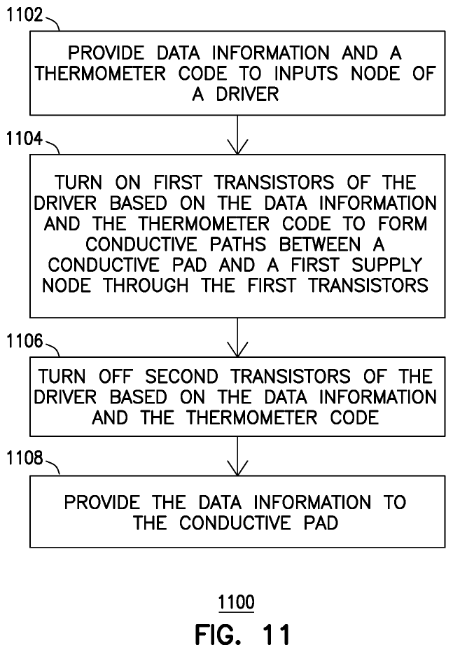

FIG. 11 shows a method 1100 of operating an apparatus, according to some embodiments described herein. Method 1100 can be performed by any of the apparatuses (e.g., apparatus 100 system 1000) described above with reference to FIG. 1 through FIG. 10. Some of the activities in method 1100 may be performed by hardware, software, firmware, or any combination of hardware, software, and firmware of a device (e.g., processor 1015, memory device 1020, memory controller 1030, graphics controller 1040, or I/O controller 1050 of system 1000) or a system (e.g., system 1000).

As shown in FIG. 11, method 1100 can include activities (e.g., operations) 1102, 1104, 1106, and 1108. Activity 1102 can include providing data information (e.g., information D) and a thermometer code (e.g., Codeᵢ_P₀ through Codeᵢ_P₃₁ and Codeᵢ_N₀ through Codeᵢ N₃₁) to input nodes of a driver (e.g., driver 110 of FIG. 2A). Activity 1104 can include turning on first transistors (e.g., at least one of transistors P₀ through P₃₁) of the driver, based on the data information and the thermometer code, to form conductive paths between a conductive pad and a first supply node through the first transistors and circuit paths coupled to the first transistors. In activity 1104, the first transistors can be coupled between the first supply node and a number of nodes. The circuit paths can include resistors coupled between the conductive pad and respective nodes of the number of nodes. The driver can include an output resistance based on resistance values of the resistors.

Activity 1106 of method 1100 can include turning off second transistors of the driver, based on value of the data information and the thermometer code. In activity 1106, the second transistors can be coupled between a second supply node and respective nodes of the number of nodes. Activity 1108 can include providing the data information to the conductive pad.

Method 1100 described above can include fewer or more activities relative to activities 1102, 1104, 1106, and 1108 shown in FIG. 11. For example, method 1100 can include providing additional data information and an additional thermometer code to the input nodes of the driver, turning on the second transistors, based on the additional data information and the additional thermometer code, to form additional conductive paths between the conductive pad and the second supply node through the second transistors and additional circuit paths coupled to the second transistors, turning off the first transistors, based on value of the additional data information and the additional thermometer code, and providing the additional data information to the conductive pad. The data information and the additional data information have different values.

Method 1100 can include additional activities including activities and operations of the apparatuses (e.g., apparatus 100 and system 1000) described above with reference to FIG. 1 through FIG. 10. Method 1100 can have improvements and benefits similar to those of apparatus 100 and system 1000.

The illustrations of the apparatuses (e.g., apparatus 100 including driver 110 and system 1000) and methods (e.g., method 1100) described above are intended to provide a general understanding of the structure of different embodiments and are not intended to provide a complete description of all the elements and features of an apparatus that might make use of the structures described herein.

Any of the components described above with reference to FIG. 1 through FIG. 11 can be implemented in a number of ways, including simulation via software. Thus, apparatuses (e.g., apparatus 100 and system 1000) may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

In the detailed description and the claims, the terms “first,” “second,” and “third,” etc. are used merely as labels, and are not intended to impose numerical requirements on their objects.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the term “adjacent” generally refers to a position of a thing being next to (e.g., either immediately next to or close to with one or more things between them) or adjoining another thing (e.g., abutting it or contacting it (e.g., directly coupled to) it).

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

Described implementations of the subject matter can include one or more features, alone or in combination as illustrated below by way of examples.

Example 1 is an apparatus comprising a conductive pad, a first supply node, a second supply node, and a driver including first transistors coupled between the first supply node and a number of nodes, second transistors coupled between the second supply node and the number of nodes, and circuit paths coupled between the conductive pad and respective nodes of the number of nodes, wherein at least one of the circuit paths includes parallel-connected resistors, and at least two of the circuit paths include a single resistor.

In Example 2, the subject matter of Example 1 includes subject matter wherein at least two of the circuit paths include a same number of parallel-connected resistors.

In Example 3, the subject matter of any of Examples 1-2 includes subject matter wherein at least three adjacent circuit paths of the circuit paths include a single resistor.

In Example 4, the subject matter of any of Examples 1-3 includes subject matter wherein the driver includes circuits coupled to respective gates of the first transistors and respective gates of the second transistors, and the circuits include respective input nodes coupled to a same data input node.

In Example 5, the subject matter of any of Examples 1-4 includes subject matter wherein the driver includes circuits coupled to respective gates of the first transistors and respective gates of the second transistors, and the circuits include input nodes to receive a thermometer code.

In Example 6, the subject matter of any of Examples 1-5 includes subject matter wherein the parallel-connected resistors and the single resistor form part of an output resistance of the driver.

In Example 7, the subject matter of any of Examples 1-5 includes subject matter wherein the parallel-connected resistors and the single resistor form part of a termination resistance of the driver.

In Example 8, the subject matter of any of Examples 1-7 includes subject matter wherein the apparatus comprises a system on chip (SoC), the SoC including an integrated circuit (IC) die, and wherein the driver is included in the IC die.

In Example 9, the subject matter of any of Examples 1-7 includes, a circuit board including conductive lines, a first device located on the circuit board and coupled to the conductive lines, and a second device located on the circuit board and coupled to the conductive lines, wherein the first device includes the driver.

In Example 10, the subject matter of any of Examples 1-9 includes subject matter wherein at least two adjacent circuit paths of the circuit paths include a same number of parallel-connected resistors.

In Example 11, the subject matter of any of Examples 1-9 includes subject matter wherein two adjacent circuit paths of the circuit paths have different number of resistors.

In Example 12, the subject matter of any of Examples 1-9 includes subject matter wherein two adjacent circuit paths of the circuit paths have different number of parallel-connected resistors.

In Example 13, the subject matter of any of Examples 1-12 includes subject matter wherein the number of nodes includes drains of the first transistors and sources of the second transistors.

In Example 14, the subject matter of any of Examples 1-13 includes subject matter wherein the first supply node is coupled to a positive voltage, the second supply node is part of a ground connection, and the conductive pad includes an input/output (I/O) conductive pad.

In Example 15, the subject matter of any of Examples 1-13 includes subject matter wherein the first transistors have a first transistor type, and the second transistors have a second transistor type.

In Example 16, the subject matter of any of Examples 1-15 includes subject matter wherein the circuits include first logic gates coupled to respective gates of the first transistors and second logic gates coupled to respective gates of the second transistors.

In Example 17, the subject matter of any of Examples 1-16 includes, a binary-to-thermometer converter to convert the binary code into a thermometer code.

In Example 18, the subject matter of any of Examples 1-17 includes subject matter wherein the resistors are structured to provide a resistance range, and the resistance range exhibits linearity profile.

Example 19 is an apparatus comprising a conductive pad, a first supply node, a second supply node, and a driver including first transistors coupled between the first supply node and a number of nodes, second transistors coupled between the second supply node and the number of nodes, and circuit paths including resistors coupled between the conductive pad and respective nodes of the number of nodes, wherein the resistors are arranged in a non-binary weighted pattern, and the resistors form part of an output resistance of the driver.

In Example 20, the subject matter of Example 19 includes subject matter wherein the resistors form part of a termination resistance of the driver.

In Example 21, the subject matter of Example 19 includes subject matter wherein the output resistance is based on resistors included in selected circuit paths of the circuit paths, wherein the selected circuit paths are adjacent to each other.

In Example 22, the subject matter of any of Examples 19-21 includes subject matter wherein the driver includes input nodes to receive a thermometer code.

In Example 23, the subject matter of any of Examples 19-22 includes subject matter wherein the resistors are structured to provide a resistance range, the resistance range including resistances encoded with code information, wherein a lower value of the code information is associated with a higher resistance of the resistance range, and a higher value of the code information is associated with a lower resistance of the resistance range.

In Example 24, the subject matter of any of Example 19-23 includes subject matter wherein the resistors are structured to provide a first resistance range for a first termination resistance, and a second resistance range for a second termination resistance.

In Example 25, the subject matter of any of Examples 19-24 includes subject matter wherein the apparatus comprises a system in a package (SiP), the SiP including an integrated circuit (IC) die, and wherein the driver is included in the IC die.

In Example 26, the subject matter of any of Examples 19-24 includes, a connector and an integrated circuit (IC) die coupled to the connector, the IC die including the driver, wherein the connector conforms with at least one of Universal Serial Bus (USB), High-Definition Multimedia Interface (HDMI), Thunderbolt, Peripheral Component Interconnect Express (PCIe), and Ethernet specifications.

In Example 27, the subject matter of any of Examples 19-26 includes subject matter wherein the resistors form part of the output resistance of the driver in for a first operating mode of the driver, and the resistors form part of a termination resistance for the driver during a second operating mode of the driver.

In Example 28, the subject matter of Example 27 includes subject matter wherein the first operating mode includes a transmitting of the driver, and the second operating mode includes a receiving mode of the driver.

In Example 29, the subject matter of any of Example 19-28 includes subject matter wherein the first transistors include p-type transistors, and the second transistor includes n-type transistors.

Example 30 is a method comprising providing data information and a thermometer code to input nodes of a driver, turning on first transistors of the driver, based on the data information and the thermometer code, to form conductive paths between a conductive pad and a first supply node through the first transistors and circuit paths coupled to the first transistors, wherein the first transistors are coupled between the first supply node and a number of nodes, the circuit paths including resistors coupled between the conductive pad and respective nodes of the number of nodes, and the driver includes an output resistance based on resistance values of the resistors, turning off second transistors of the driver, based on value of the data information and the thermometer code, the second transistors coupled between a second supply node and respective nodes of the number of nodes, and providing the data information to the conductive pad.

In Example 31, the subject matter of Example 30 includes, providing additional data information and an additional thermometer code to the input nodes of the driver, turning on the second transistors, based on the additional data information and the additional thermometer code, to form additional conductive paths between the conductive pad and the second supply node through the second transistors and additional circuit paths coupled to the second transistors, turning off the first transistors, based on value of the additional data information and the additional thermometer code, and providing the additional data information to the conductive pad.

In Example 32, the subject matter of Example 31 includes subject matter wherein the data information and the additional data information have different value.

In Example 33, the subject matter of any of Examples 30-32 includes subject matter wherein the data information is a bit of data having a first value, and the additional data information is a bit of information having a second value.

In Example 34, the subject matter of any of Examples 30-33 includes subject matter wherein the first supply node is coupled to a positive voltage, the second supply node is part of a ground connection, and the conductive pad includes and input/output (I/O) conductive pad.

In Example 35, the subject matter of any of Examples 30-34 includes subject matter wherein the second supply node is coupled to a positive voltage, the first supply node is part of a ground connection, and the conductive pad includes and input/output (I/O) conductive pad.

Example 36 is at least one machine-readable medium including instructions that, when executed by processing circuitry, cause the processing circuitry to perform operations to implement any of Examples 1-35.

Example 37 is an apparatus comprising means to implement any of Examples 1-35.

Example 38 is a system to implement any of Examples 1-35.

Example 39 is a method to implement any of Examples 1-35.

The subject matter of Examples 1-39 may be combined in any combination.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a conductive pad;
a first supply node;
a second supply node; and
a driver including:
first transistors coupled between the first supply node and a number of nodes;
second transistors coupled between the second supply node and the number of nodes; and
circuit paths coupled between the conductive pad and respective nodes of the number of nodes, wherein at least one of the circuit paths includes parallel-connected resistors, and at least two of the circuit paths include a single resistor.

2. The apparatus of claim 1, wherein at least two of the circuit paths include a same number of parallel-connected resistors.

3. The apparatus of claim 1, wherein at least three adjacent circuit paths of the circuit paths include a single resistor.

4. The apparatus of claim 1, wherein the driver includes circuits coupled to respective gates of the first transistors and respective gates of the second transistors, and the circuits include respective input nodes coupled to a same data input node.

5. The apparatus of claim 1, wherein the driver includes circuits coupled to respective gates of the first transistors and respective gates of the second transistors, and the circuits include input nodes to receive a thermometer code.

6. The apparatus of claim 1, wherein the parallel-connected resistors and the single resistor form part of an output resistance of the driver.

7. The apparatus of claim 1, wherein the parallel-connected resistors and the single resistor form part of a termination resistance of the driver.

8. The apparatus of claim 1, wherein the apparatus comprises a system on chip (SoC), the SoC including an integrated circuit (IC) die, and wherein the driver is included in the IC die.

9. The apparatus of claim 1, further comprising:
a circuit board including conductive lines;
a first device located on the circuit board and coupled to the conductive lines; and
a second device located on the circuit board and coupled to the conductive lines, wherein the first device includes the driver.

10. An apparatus comprising:
a conductive pad;
a first supply node;
a second supply node; and
a driver including:
first transistors coupled between the first supply node and a number of nodes;
second transistors coupled between the second supply node and the number of nodes; and
circuit paths including resistors coupled between the conductive pad and respective nodes of the number of nodes, wherein the resistors are arranged in a non-binary weighted pattern, and the resistors form part of an output resistance of the driver.

11. The apparatus of claim 10, wherein the resistors form part of a termination resistance of the driver.

12. The apparatus of claim 10, wherein the output resistance is based on resistors included in selected circuit paths of the circuit paths, wherein the selected circuit paths are adjacent to each other.

13. The apparatus of claim 10, wherein the driver includes input nodes to receive a thermometer code.

14. The apparatus of claim 10, wherein the resistors are structured to provide a resistance range, the resistance range including resistances encoded with code information, wherein a lower value of the code information is associated with a higher resistance of the resistance range, and a higher value of the code information is associated with a lower resistance of the resistance range.

15. The apparatus of claim 10, wherein the resistors are structured to provide a first resistance range for a first termination resistance, and a second resistance range for a second termination resistance.

16. The apparatus of claim 10, wherein the apparatus comprises a system in a package (SiP), the SiP including an integrated circuit (IC) die, and wherein the driver is included in the IC die.

17. The apparatus of claim 10, further comprising a connector and an integrated circuit (IC) die coupled to the connector, the IC die including the driver, wherein the connector conforms with at least one of Universal Serial Bus (USB), High-Definition Multimedia Interface (HDMI), Thunderbolt, Peripheral Component Interconnect Express (PCIe), and Ethernet specifications.

18. A method comprising:
providing data information and a thermometer code to input nodes of a driver;
turning on first transistors of the driver, based on the data information and the thermometer code, to form conductive paths between a conductive pad and a first supply node through the first transistors and circuit paths coupled to the first transistors, wherein the first transistors are coupled between the first supply node and a number of nodes, the circuit paths including resistors coupled between the conductive pad and respective nodes of the number of nodes, and the driver includes an output resistance based on resistance values of the resistors;
turning off second transistors of the driver, based on value of the data information and the thermometer code, the second transistors coupled between a second supply node and respective nodes of the number of nodes; and
providing the data information to the conductive pad.

19. The method of claim 18, further comprising:
providing additional data information and an additional thermometer code to the input nodes of the driver;
turning on the second transistors, based on the additional data information and the additional thermometer code, to form additional conductive paths between the conductive pad and the second supply node through the second transistors and additional circuit paths coupled to the second transistors;
turning off the first transistors, based on value of the additional data information and the additional thermometer code; and
providing the additional data information to the conductive pad.

20. The method of claim 19, wherein the data information and the additional data information have different values.
